(19) United States
(12) Patent Application Publication
(10) Pub. No.: US 2003/0183905 A1
(43) Pub. Date: Oct. 2, 2003

(54) Interconnection structure and interconnection structure formation method

(75) Inventor: Katsuyuki Karakawa, Kasugai (JP)

Correspondence Address: ARMSTRONG,WESTERMAN & HATTORI, LLP, 1725 K STREET, NW, SUITE 1000, WASHINGTON, DC, 20006, US

(73) Assignee: FUJITSU LIMITED, Kawasaki (JP)

(21) Appl. No.: 10/421,699

(22) Filed: Apr. 24, 2003

Related U.S. Application Data
(63) Continuation-in-part of application No. 10/198,939, filed on Jul. 22, 2002.

(30) Foreign Application Priority Data
Feb. 14, 2002 (JP) 2002-037392
Feb. 14, 2003 (JP) 2003-037311

(51) Int. Cl. H01L 23/58

(52) U.S. Cl. 257/637

(57) ABSTRACT

As a protective film corresponding to a Cu interconnection, a protective film having a function of preventing diffusion of the Cu and a function as an etching stopper when a via hole is formed, and also having a low dielectric constant is proposed. This protective film has a two-layered structure in which a silicon nitride film (SiN film) is stacked on a hydrogenated silicon carbide film (SiC:H film).

### CROSS-REFERENCE TO RELATED APPLICATIONS

This is a continuation-in-part application of application Ser. No. 10/198,939, filed Jul. 22, 2002.

This application is based upon and claims the benefit of priority from the prior Japanese Patent Application Nos. 2002-037392, filed on Feb. 14, 2002 and 2003-037311, filed on Feb. 14, 2003 the entire contents of which are incorporated herein by reference.

### BACKGROUND OF THE INVENTION

1. Field of the Invention

The present invention relates to an interconnection structure primarily used in a semiconductor device and a method of forming the same, and can be suitably applied to an interconnection structure in which an interconnection is made of a material containing at least copper (Cu).

2. Description of the Related Art

With the recent high integration of semiconductor elements and downsizing of chips, micropatterned interconnections and multilayer interconnections are acceleratedly advanced. In a logic device having such a multilayer interconnection, a wiring delay is becoming a dominant cause of a device signal delay. A signal delay of a device is proportional to the product of the wiring resistance and the wiring capacitance. Accordingly, it is important for improving the interconnection delay to reduce the wiring resistance and the wiring capacitance.

To reduce the wiring resistance, therefore, the formation of a Cu interconnection is being studied. Since Cu is difficult to process, a so-called damascene structure in which an interconnection groove formed in an insulating film is filled with Cu is attracting attention as a suitable structure when Cu is applied to an interconnection.

Cu readily diffuses into an interlayer insulating film such as an oxide film. When a Cu interconnection is formed, therefore, a protective film whose main purpose is to prevent this diffusion must be formed between the Cu interconnection and an interlayer insulating film above this Cu interconnection. As this protective film, a silicon nitride film having high oxidation resistance is conventionally used. A silicon nitride film has a relatively low etching rate and hence functions as an etching stopper. However, a silicon nitride film has a high dielectric constant, so the formation of a silicon nitride film increases the interlayer capacitance.

### SUMMARY OF THE INVENTION

The present invention has been made to solve this problem, and has as its object to provide an interconnection structure which, when an interconnection is formed using a material, represented by a Cu-containing material, which easily diffuses into an interlayer insulating film, reliably prevents diffusion of this easily diffusible material into an interlayer insulating film and prevents peeling of the material, which reduces the interlayer capacitance, and which maintains high oxidation resistance to realize high reliability, and to provide a method of forming this interconnection structure.

The present inventor made extensive studies, and has reached the following aspects of the invention.

An interconnection structure formation method according to the present invention comprises the first step of forming a lower interconnection above a substrate, the second step of forming a first protective film made of silicon carbide so as to cover the surface of the lower interconnection, the third step of forming a second protective film made of an insulating material on the first protective film, the fourth step of forming an interlayer insulating film on the second protective film, the fifth step of forming a hole in the interlayer insulating film with using the second protective film as a stopper, the sixth step of processing an upper layer portion of the interlayer insulating film in a portion aligned with the hole, the seventh step of processing the second and first protective films so as to be aligned with the hole, thereby exposing the surface of the lower interconnection to the hole, and the eighth step of burying a conductive material in at least the hole.

Another aspect of the interconnection structure formation method of the present invention comprises the steps of forming a lower interconnection above a substrate, forming a first protective film made of silicon carbide so as to cover one surface of the lower interconnection, forming a second protective film made of an insulating material on the first protective film, forming a third protective film made of silicon carbide on the second protective film, forming an interlayer insulating film on the third protective film, forming a hole in the interlayer insulating film by using the third protective film as a stopper, processing an upper layer portion of the interlayer insulating film in a portion aligned with the hole, processing the second and first protective films so as to be aligned with the hole, thereby exposing one surface of the lower interconnection to the hole, and burying a conductive material in at least the hole.

In another aspect of the interconnection structure formation method according to the present invention comprises the steps of forming a first protective film made of silicon carbide, a second protective film made of an insulating material, and an interlayer insulating film in this order so as to cover the surface of a lower interconnection, forming a hole in the interlayer insulating film with using the second protective film as a stopper, and removing a mask used in forming the hole while the surface of the second protective film is exposed to the hole.

Another aspect of the interconnection structure formation method of the present invention comprises the steps of forming a first protective film made of silicon carbide, a second protective film made of an insulating material, a third protective film made of silicon carbide, and an interlayer insulating film in this order so as to cover one surface of a lower interconnection, forming a hole in the interlayer insulating film by using the third protective film as a stopper, and removing a mask used in forming the hole while a surface of the third or second protective film is exposed to the hole.

An interconnection structure of the present invention comprises a lower interconnection formed above a substrate, a first protective film made of silicon carbide and formed to cover the lower interconnection, a second protective film made of an insulating material and formed on the first protective film, an interlayer insulating film formed on the second protective film, and an upper interconnection electrically connected to the lower interconnection through a hole formed in the interlayer insulating film, the second protective film and the first protective film.

Another aspect of the interconnection structure of the present invention comprises a lower interconnection formed above a substrate, a first protective film made of silicon carbide and formed to cover the lower interconnection, a second protective film made of an insulating material and formed on the first protective film, a third protective film made of silicon carbide and formed on the second protective film, an interlayer insulating film formed on the third protective film, and an upper interconnection electrically connected to the lower interconnection through a hole formed in the interlayer insulating film and the third, second, and first protective films.

### BRIEF DESCRIPTION OF THE DRAWINGS

FIG. 1 is a graph showing the reduction amount of an SiC:H film when an SiN film is formed on this SiC:H film and ashing is performed; and

FIGS. 2A to 2E are schematic sectional views showing a method of forming an interconnection structure according to the first embodiment of the present invention in order of steps.

FIGS. 3A to 3C are schematic sectional views following FIGS. 2A to 2E to show the interconnection structure formation method according to the first embodiment in order of steps;

FIGS. 4A to 4C are schematic sectional views following FIGS. 3A to 3C to show the interconnection structure formation method according to the first embodiment in order of steps;

FIGS. 5A to 5C are schematic sectional views showing an interconnection structure formation method according to the second embodiment in order of steps;

FIGS. 6A to 6C are schematic sectional views following FIGS. 5A to 5C to show the interconnection structure formation method according to the second embodiment in order of steps; and

FIGS. 7A to 7C are schematic sectional views following FIGS. 6A to 6C to show the interconnection structure formation method according to the second embodiment in order of steps.

### DETAILED DESCRIPTION OF THE PREFERRED EMBODIMENT

Main Constitution of Present Invention

First, the main constitution of the present invention will be explained below together with its operating principle.

A silicon carbide (SiC) film (more specifically, a hydrogenated silicon carbide (SiC:H) film, and this expression will be used hereinafter) is regarded as a promising low-dielectric-constant protective film which can replace a silicon nitride film when an interconnection is formed using an interconnection material, represented by a Cu-containing material, which easily diffuses into an interlayer insulating film.

Unfortunately, the oxidation resistance of SiC:H is a problem if this SiC:H protective film is used to prevent Cu diffusion and as an etching stopper when a hole is formed in an interlayer insulating film as an upper layer. That is, after the hole is formed, a resist mask used in the hole formation is removed by ashing using an oxygen plasma while the surface of the protective film is partially exposed to the hole. By this ashing process, the surface of the protective film and, in some cases, the interior of the film are oxidized. Since this increases the etching rate of the protective film, the protective film which is supposed not to be etched is etched, resulting in an abnormal hole shape or unexpected etching in the lower layer structure.

As a protective film suited to an interconnection made of an easily diffusible material, the present invention proposes a protective film having a structure which can prevent diffusion of the material and can function as an etching stopper, and which has a low dielectric constant. This protective film is tipically a two-layered structure in which a silicon nitride film (SiN film) is formed on an SiC:H film.

An optimum value of the film thickness of the SiN film as a cap film of the SiC:H film is determined as follows.

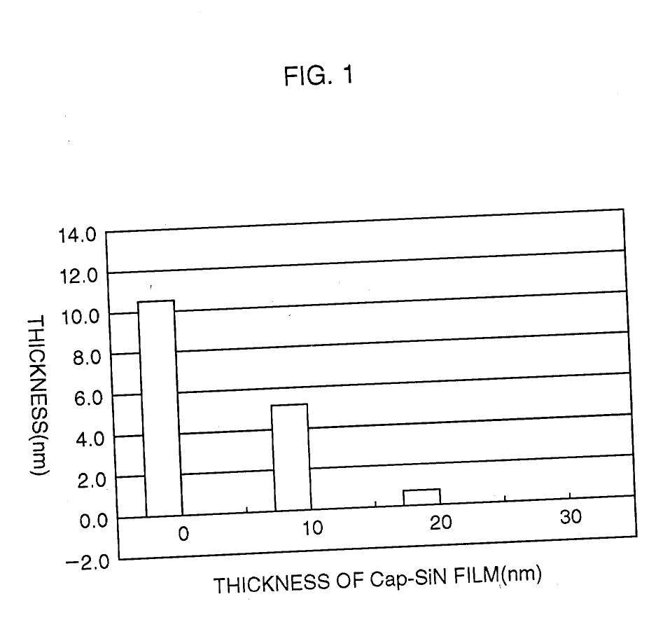

FIG. 1 is a graph showing the reduction amount of an SiC:H film when an SiN film is formed on this SiC:H film and ashing is performed. In this graph, the reduction amount of the SiC:H film is proportional to the oxidation amount of this SiC:H film by ashing. This graph shows that when the film thickness of the SiN film on the SIC:H film is 20 nm or less, the SIC:H film is oxidized by ashing and so the film thickness of this SiC:H film reduces; when the film thickness of the SiN film is more than 20 nm, the amount of the SIC:H film does not reduce. Therefore, the SiN film preferably has a film thickness of more than 20 nm.

In addition, when the function of this SiN film as an etching stopper is taken into consideration and the film reduction amount by etching is estimated to be about 30 nm, the film thickness of the SiN film need only be 50 nm or more.

For example, when the two-layered protective film described above is formed to cover a Cu interconnection formed by the damascene process, an interlayer insulating film is formed on this protective film, and a hole is formed for the Cu interconnection. More specifically, the hole is formed with using the SiN film, which is an upper layer of the protective film, as a stopper. After the hole is formed, a resist pattern used in forming the hole is removed by ashing while the surface of the SiN film is partially exposed to the bottom of the hole. Since this SiN film has high oxidation resistance, oxidation of the SIC:H film below the SiN film and the Cu interconnection is prevented.

When this Cu interconnection is used as a lower interconnection and another Cu interconnection is to be formed as an upper interconnection on the interlayer insulating film by the damascene process, an interconnection groove is formed in the interlayer insulating film, and the protective film is so processed as to be aligned with the hole until the surface of the lower Cu interconnection is partially exposed. After that, an upper Cu interconnection is formed to fill the interconnection groove and the hole.

In the present invention as described above, a protective film of a Cu interconnection is formed to have the aforementioned two-layered structure. The upper SiN film can reliably function as an etching stopper during hole formation and prevent oxidation of the lower structure. The lower SiC:H film having a low dielectric constant can reduce the interlayer capacitance. That is, this protective film reliably prevents diffusion of Cu as its original purpose, and also functions as an etching stopper. In addition, the protective film reliably achieves the oxidation preventing function when serving as an etching stopper, thereby implementing a highly reliable interconnection structure.

In the present invention as described above, a protective film is made of a material (to be explained as an SiN film hereinafter) having both an etching stop function and oxidation inhibiting function, and a material (SiC:H) having a low interlayer capacitance. To decrease the interlayer capacitance, the ratio of the SiN film in the protective film must be made as small as possible.

The present inventor, therefore, studied a protective film whose oxidation inhibiting function is given highest priority while only the minimum necessary demand for an SiN film as an etching stopper is satisfied, and has reached the use of a protective film having a triple structure in which an SIN film is sandwiched by SiC:H films and, when holes are formed in an interlayer insulating film, etching is performed by regarding the uppermost SIC:H film as an etching stopper. In this structure, the SIC:H film also has an etching stop function although this function is inferior to that of the SIN film, and the SiN film is present below this SIC:H film. Therefore, even when this silicon oxide film is made thin to such an extent that the film cannot well achieve an etching stop function by itself, in order to exclusively achieve the oxidation inhibiting function, a satisfactory etching stopping effect can be obtained by the two-layered film made up of this silicon oxide film and the overlying SIC:H film as a whole.

In the present invention as described above, a protective film of a Cu interconnection is formed into the three-layered structure described above. In this structure, the upper SIC:H film and the SiN film can well function as etching stoppers when holes are formed, the SiN film can reliably prevent oxidation of the lower structure, and the upper and lower SIC:H films having a low dielectric constant can decrease the interlayer capacitance. That is, the use of this protective film reliably prevents Cu diffusion, and greatly reduces the interlayer capacitance by making the SiN film as thin as possible. In addition, the protective film not only functions as an etching stopper but also reliably achieves an oxidation inhibiting effect when functioning as an etching stopper, thereby realizing a highly reliable interconnection structure.

Practical Embodiment

On the basis of the main constitution described above, a practical embodiment of the present invention will be described in detail below with reference to the accompanying drawings. In this embodiment, a general MOS transistor is taken as an example of a semiconductor device, and the present invention is applied to its interconnection structure. For the sake of convenience, this interconnection structure will be explained along with its formation method.

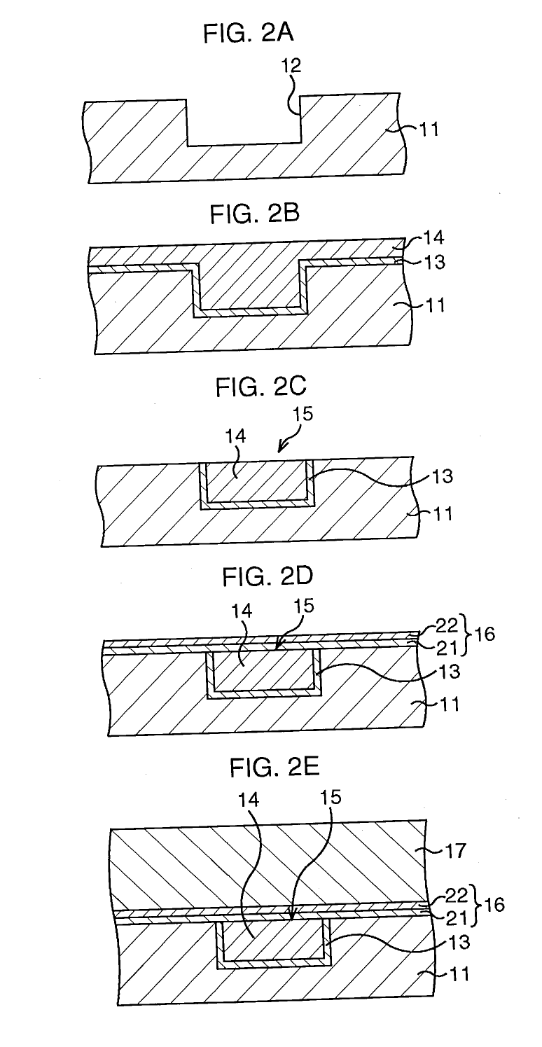

FIGS. 2A to 2E are schematic sectional views showing the interconnection structure formation method according to this embodiment in order of steps.

Prior to formation of this interconnection structure, a MOS transistor structure having a gate electrode and source/drains is formed on a silicon wafer. The present invention is applied to an interconnection structure electrically connected to, e.g., the source/drain of this MOS transistor.

First, as shown in FIG. 2A, an interlayer insulating film 11 which is a silicon oxide film is deposited by a CVD method so as to cover the MOS transistor on the silicon semiconductor substrate (neither is shown). After that, a lower Cu interconnection is formed by a so-called damascene process. Note that a silicon fluoride oxide film or an organic insulating film may be formed instead of the silicon oxide film.

More specifically, the interlayer insulating film 11 is coated with a photoresist (not shown), and this photoresist is formed into the shape of an interconnection by photolithography. The interlayer insulating film 11 is then dry-etched by using this photoresist as a mask, thereby forming an interconnection groove 12 having the shape of the photoresist in the interlayer insulating film 11.

Subsequently, as shown in FIG. 2B, a TaN barrier metal film 13 about 25 nm thick is formed on the interlayer insulating film 11 so as to cover the inner wall surfaces of the interconnection groove 12. Then, a Cu film (not shown) is deposited as a seed metal film. The TaN barrier metal film 13 and the seed metal film are continuously formed in a vacuum by a sputtering apparatus. Note that the RF processing and the formation of the barrier metal film 13 and the seed metal film are desirably continuously performed in a vacuum.

By using the seed metal film as an electrode, a Cu film 14 is formed by plating so as to have a film thickness, about 1 μm in this embodiment, with which the interconnection groove 12 is filled.

As shown in FIG. 2C, to isolate the Cu film 14 by the damascene process, the Cu film 14 and the barrier metal film 13 are polished by a CMP (Chemical Mechanical Polishing) method so as to remain only in the interconnection groove 12, thereby forming a lower Cu interconnection 15.

Subsequently, an upper Cu interconnection to be electrically connected to the lower Cu interconnection 15 through a via hole is formed.

More specifically, as shown in FIG. 2D, the two-layered protective film of the present invention is formed so as to cover the surface of the lower Cu interconnection 15.

First, an SiC:H film 21 about 20 nm thick is formed on the lower Cu interconnection 15 by a plasma CVD method. Then, an SiN film 22 about 50 nm thick is formed on the SiC:H film 21 by a plasma CVD method. The film thickness of this SiN film 22 is determined on the basis of the above-mentioned consideration. The SiC:H film 21 and the SiN film 22 construct a protective film 16.

The formation conditions of the SiN film 22 are as follows. SiH₄ gas, NH₃ gas, and N₂ gas are supplied into the chamber at flow rates of 500, 3,800, and 3,800 sccm, respectively. The chamber pressure is 220 Pa, the 13.56-MHz RF power is 500 W, the 250-kHz low-frequency power is 350 W, and the substrate (substrate stage) temperature is 400° C.

Subsequently, as shown in FIG. 2E, an interlayer insulating film 17 which is a silicon oxide film about 1,200 nm thick is formed on the protective film 16 by a CVD method. Note that a silicon fluoride oxide film or an organic insulating film may be formed instead of the silicon oxide film.

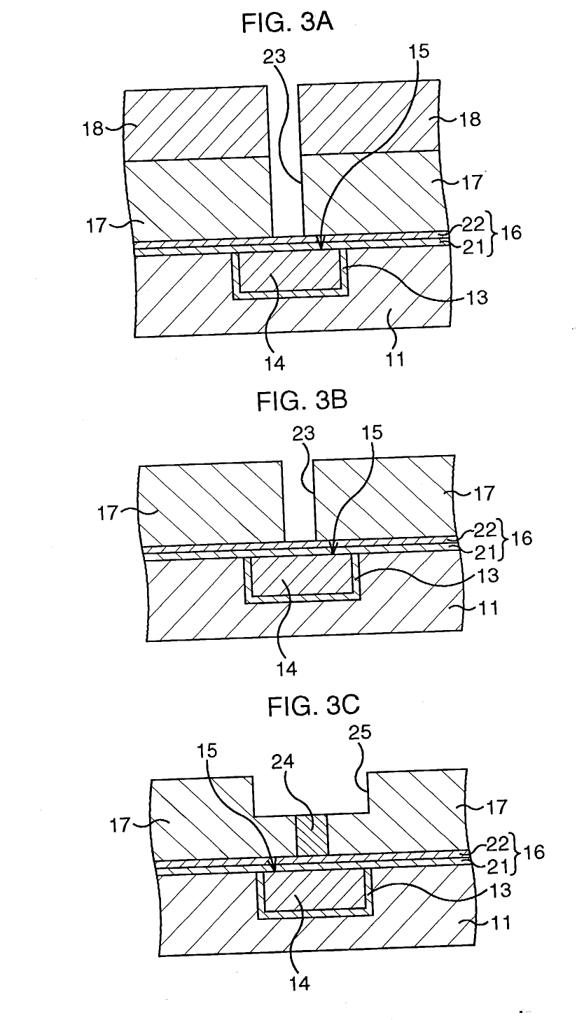

As shown in FIG. 3A, the interlayer insulating film 17 is coated with a photoresist, and this photoresist is processed by photolithography to form a resist pattern 18 having a hole pattern. By using this resist pattern as a mask, the interlayer insulating film 17 is etched with a C₄F₈/O₂-based etching gas by using the SiN film 22 in the protective film 16 as an etching stopper, thereby forming a via hole 23.

As shown in FIG. 3B, a CF₄/O₂-based etching gas is used to remove the unnecessary resist pattern 18 by ashing performed by an RIE (Reactive Ion Etching) method. During this ashing, a portion of the SiN film 22 as a cap layer of the protective film 16 is exposed to the bottom of the via hole 23. However, the SiN film 22 has oxidation resistance, so oxidation of the lower SiC:H film 21 and the lower Cu interconnection 15 by oxygen radicals is prevented. Since the SiC:H film 21 is neither damaged by etching nor modified by oxidation, this SiC:H film 21 well functions as a Cu diffusion preventing film.

As shown in FIG. 3C, the via hole 23 is filled with a resin 24. In this state, the interlayer insulating film 17 is coated with a photoresist, and this photoresist is processed by photolithography to form a resist pattern (not shown) having an interconnection groove pattern. This resist pattern is used as a mask to etch the interlayer insulating film 17 (and a portion of the resin 24), forming an interconnection groove 25.

Subsequently, a CF₄/O₂-based etching gas is used to remove the unnecessary resist pattern and the resin 24 in the via hole 23 by ashing performed by RIE.

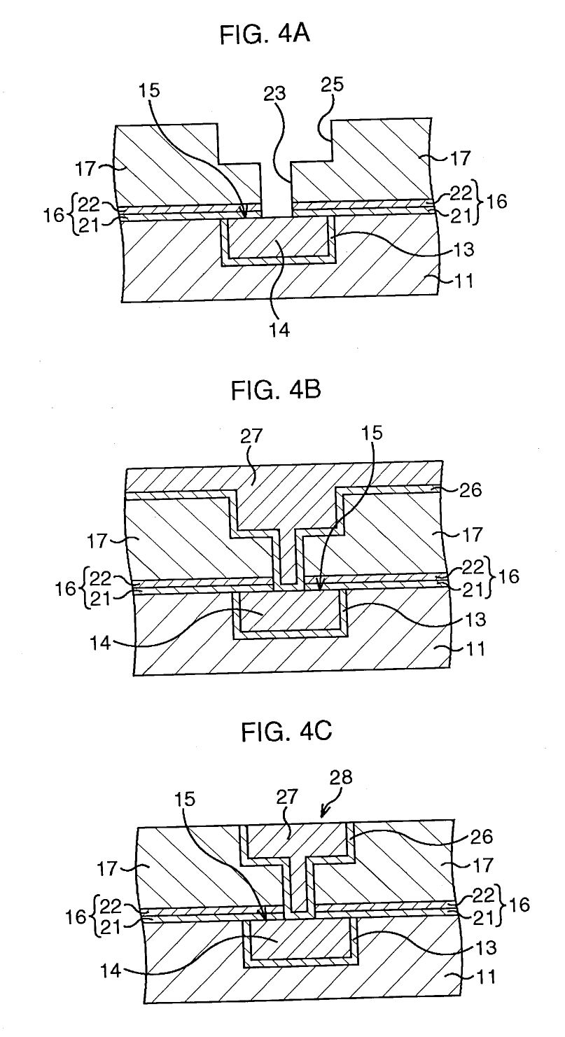

As shown in FIG. 4A, a C₄F₈/O₂-based etching gas is used to etch the protective film 16 in self-alignment with the via hole 23, thereby extending this via hole 23 such that the surface of the lower Cu interconnection 15 is partially exposed to the bottom of the via hole 23.

As shown in FIG. 4B, a TaN barrier metal film 26 about 25 nm thick is formed on the interlayer insulating film 17 so as to cover the inner wall surfaces of the interconnection groove 25 and the via hole 23. In addition, a Cu film (not shown) is deposited as a seed metal film. The TaN barrier metal film 26 and the seed metal film are continuously formed in a vacuum by a sputtering apparatus. Note that the RF processing and the formation of the barrier metal film 26 and the seed metal film are desirably continuously performed in a vacuum.

By using the seed metal film as an electrode, a Cu film 27 is formed by plating so as to have a film thickness, about 1,300 nm in this embodiment, with which the interconnection groove 25 and the via hole 23 are filled.

As shown in FIG. 4C, to isolate the Cu film 27 by the damascene process, the Cu film 27 and the barrier metal film 26 are polished by a CMP (Chemical Mechanical Polishing) method so as to remain only in the interconnection groove 25 and the via hole 23, thereby forming an upper Cu interconnection 28.

Through the above steps, an interconnection structure in which the lower Cu interconnection 15 and the upper Cu interconnection 28 are electrically connected through the via hole 23 is completed.

After that, interlayer insulating films, via holes, and interconnects are further formed to complete a MOS transistor having the above interconnection structure.

The interconnection structure of this embodiment as explained above can reliably prevent Cu diffusion from the lower Cu interconnection 15 to the interlayer insulating film 17 and prevent peeling of the Cu film 14. This interconnection structure can also reduce the interlayer capacitance, maintain high oxidation resistance, and well achieve the function as an etching stopper. This realizes a highly integrated, micropatterned, high-reliability semiconductor device having this interconnection structure.

(Second Embodiment)

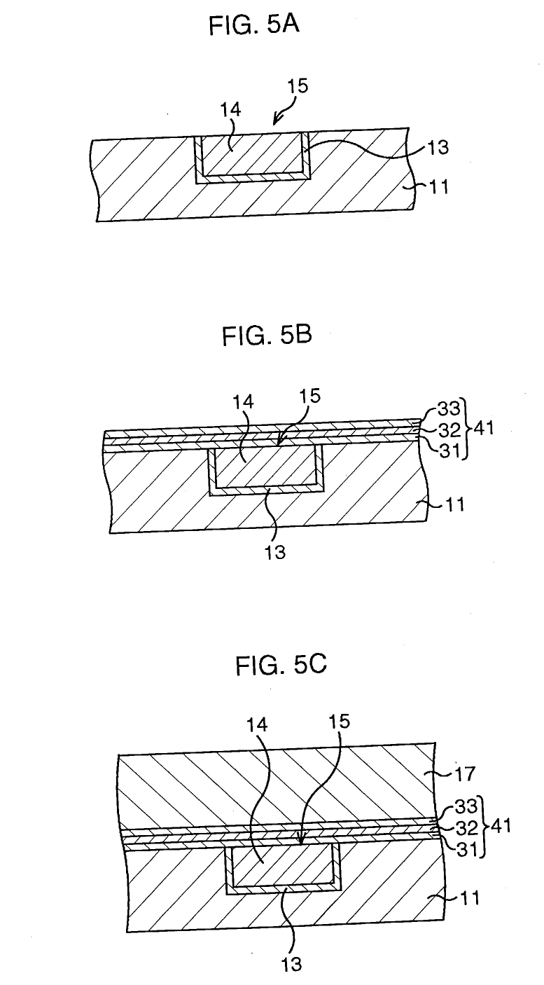

FIGS. 5A to 7C are schematic sectional views showing a method of forming an interconnection structure according to the second embodiment in order of steps.

Prior to the formation of this interconnection structure, as in the first embodiment described previously, a lower Cu interconnection 15 is formed by burying, via a barrier metal film 13, a Cu film 14 in an interconnection groove 12 of an interlayer insulating film 11 by the damascene process through the steps shown in FIGS. 2A to 2C.

Subsequently, an upper Cu interconnection to be electrically connected to the lower Cu interconnection 15 through a via hole is formed.

More specifically, as shown in FIG. 5A, a protective film having the three-layered structure of the present invention is so formed as to cover the surface of the lower Cu interconnection 15.

First, a lower SiC:H film 31 about 20 nm thick is formed on the lower Cu interconnection 15 by a plasma CVD method. Next, an SiN film 32 having a thickness of 20 to 25 nm, in this embodiment 20 nm, is formed on the SiC:H film 31 by plasma CVD. If the thickness of the SiC:H film 31 is smaller than 20 nm, no oxidation preventing effect can be achieved. On the other hand, a thickness smaller than 25 nm is necessary to well reduce the interlayer capacitance of the entire protective film. Then, an upper SiC:H film 33 about 30 nm thick is formed on the SiN film 32 by a plasma CVD method. It is preferable to thus make the SiN film 32 thinner than the upper SiC:H film 33. The thicknesses of these SiC:H films 31 and 33 are determined on the basis of the consideration described above. A protective film 41 is made up of the lower SiC:H film 31, SiN film 32, and upper SiC:H film 33.

The formation conditions of the SiN film 32 were as follows. SiH₄ gas, NH₃ gas, and N₂ gas were supplied into a chamber at flow rates of 500, 3,800, and 3,800 sccm, respectively, the chamber pressure was set at 220 Pa, a high frequency of 13.56 MHz was set at 500 W, a low frequency of 250 kHz was set at 350 W, and the substrate (substrate stage) temperature was set at 400° C.

Subsequently, as shown in FIG. 5C, an interlayer insulating film 17 which is a silicon oxide film about 1,200 nm thick is formed on the protective film 41. Note that a silicon fluoride oxide film or organic insulating film may also be formed instead of the silicon oxide film.

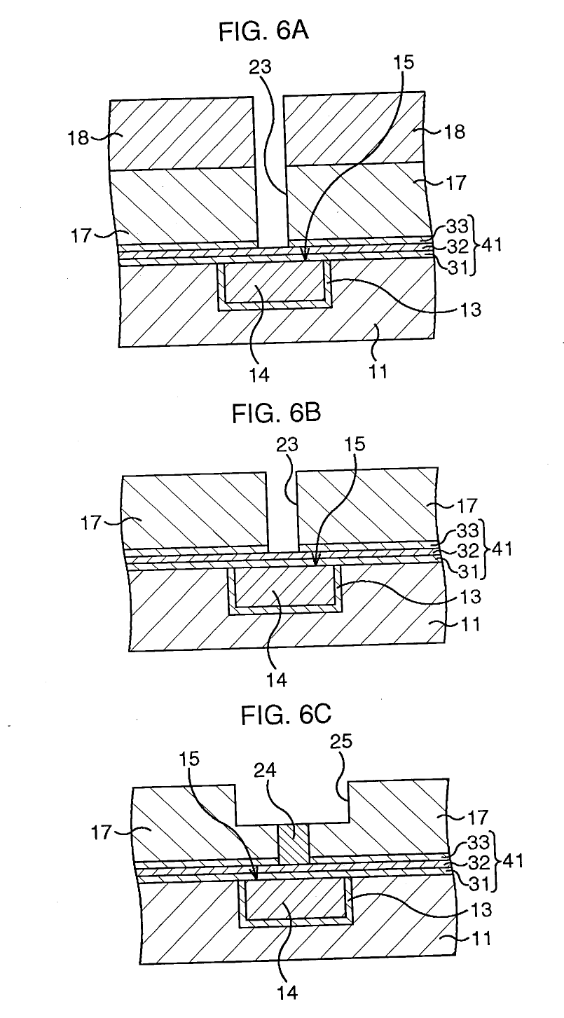

As shown in FIG. 6A, the interlayer insulating film 17 is coated with a photoresist, and this photoresist is processed to form a resist pattern 18 having a hole pattern. By using this resist pattern 18 as a mask, the interlayer insulating film 17 is etched with a C₄F₈/O₂-based etching gas by using the upper SiC:H film 33 of the protective film 41 as an etching stopper, thereby forming a via hole 23. The SiN layer 32 is slightly exposed by this etching or penetration even with the use of the upper SiC:H layer 33 as an etching stopper. However, when this upper SiC:H layer 33 is used as an etching stopper, etching is terminated at least on the surface of the SiN layer 32. Therefore, the upper SiC:H layer 33 well functions as an etching stopper in the whole two-layered structure of this upper SiC:H layer 33 and the SiN layer 32. Referring to FIG. 6A, the SiN layer 32 is partially exposed.

As shown in FIG. 6B, a CF₄/O₂-based etching gas is used to remove the unnecessary resist pattern 18 by ashing performed by an RIE (Reactive Ion Etching) method. Although a portion of the upper SiC:H film 33 or a portion of the SiN film 32 as a cap film of the protective film 41 is exposed from the bottom of the via hole 23, oxidation of the lower SiC:H film 31, lower Cu interconnection 15, and the like by oxygen radicals is prevented because the SiN film 32 has an oxidation resistance. Since the lower SiC:H film 31 is neither damaged by etching nor modified by oxidation, this lower SiC:H film 31 well functions as a Cu diffusion preventing film.

As shown in FIG. 6C, the via hole 23 is filled with a resin 24. In this state, the interlayer insulating film 17 is coated with a photoresist, and this photoresist is processed by photolithography to form a resist pattern (not shown) having an interconnection groove pattern. This resist pattern is used as a mask to etch the interlayer insulating film 17 (and a portion of the resin 24), thereby forming an interconnection groove 25.

Subsequently, a CF₄/O₂-based etching gas is used to remove the unnecessary resist pattern and the resin 24 in the via hole 23 by ashing performed by RIE.

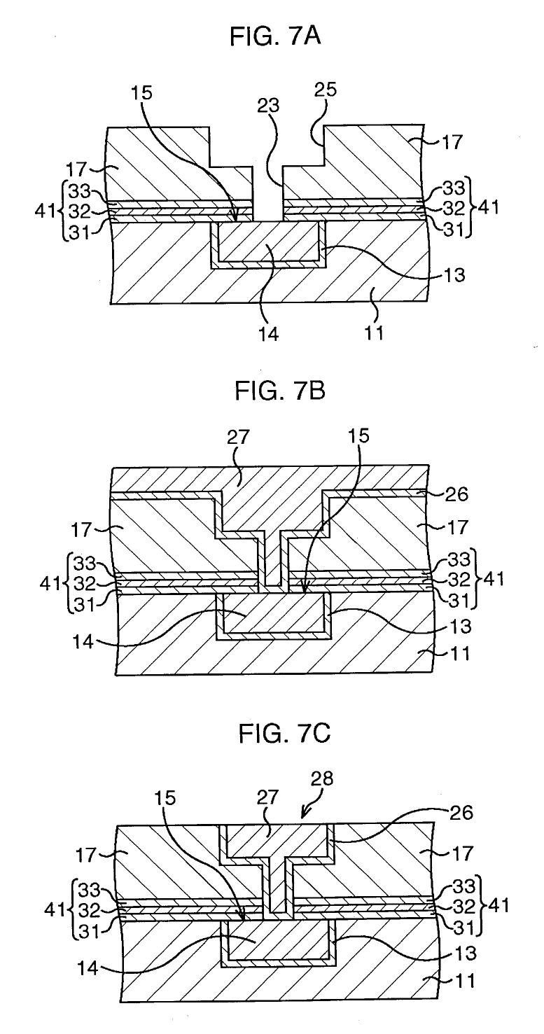

As shown in FIG. 7A, a C₄F₈/O₂-based etching gas is used to etch the protective film 41 in self-alignment with the via hole 23, thereby extending the via hole 23 such that the surface of the lower Cu interconnection 15 is partially exposed to the bottom of this via hole 23.

As shown in FIG. 7B, a TaN barrier metal layer 26 about 25 nm thick and a Cu film (not shown) as a seed metal film are continuously deposited on the interlayer insulating film 17 in a vacuum by using a sputtering apparatus, so as to cover the inner wall surfaces of the interconnection groove 25 and via hole 23. The RF processing and the formation of the barrier metal film 26 and seed metal film are desirably continuously performed in a vacuum.

By using the seed metal film as an electrode, a Cu film 27 is formed by plating so as to have a thickness, about 1,300 nm in this embodiment, with which the interconnection groove 25 and via hole 23 are filled.

As shown in FIG. 7C, to isolate the Cu film 27 by the damascene process, the Cu film 27 and barrier metal film 26 are polished by a CMP (Chemical Mechanical Polishing) method so as to remain only in the interconnection groove 25 and via hole 23, thereby forming an upper Cu interconnection 28.

Through the above steps, an interconnection structure in which the lower Cu interconnection 15 and upper Cu interconnection 28 are electrically connected through the via hole 23 is completed.

After that, interlayer insulating films, via holes, and interconnections are further formed to complete a MOS transistor having the above interconnection structure.

The interconnection structure of this embodiment as explained above can reliably prevent Cu diffusion from the lower Cu interconnection 15 to the interlayer insulating film 17 and prevent peeling of the Cu film 14. This interconnection structure can also reduce the interlayer capacitance, maintain high oxidation resistance, and well achieve the function as an etching stopper. This realizes a highly integrated, micropatterned, high-reliability semiconductor device having this interconnection structure.

In this embodiment, a MOS transistor is taken as an example of a semiconductor device. However, the present invention is not limited to this embodiment, and the interconnection structure of the invention can be suitably applied to any semiconductor device which is highly integrated and micropatterned by using Cu interconnects formed by the damascene process.

As has been described above, the present invention realizes an interconnection structure which, when an interconnection is formed using a material, represented by a Cu-containing material, which easily diffuses into an interlayer insulating film, reliably prevents diffusion of this easily diffusible material into an interlayer insulating film and prevents peeling of the material, which reduces the interlayer capacitance, and which maintains high oxidation resistance to achieve high reliability.

What is claimed is:

1. An interconnection structure formation method comprising:
first step of forming a lower interconnection above a substrate;
second step of forming a first protective film made of silicon carbide so as to cover the surface of said lower interconnection;
third step of forming a second protective film made of an insulating material on said first protective film;
fourth step of forming an interlayer insulating film on said second protective film;
fifth step of forming a hole in said interlayer insulating film with using said second protective film as a stopper;
sixth step of processing an upper layer portion of said interlayer insulating film in a portion aligned with said hole;
seventh step of processing said second and first protective films so as to be aligned with said hole, thereby exposing the surface of said lower interconnection to said hole; and
eighth step of burying a conductive material in at least said hole.

2. An interconnection structure formation method comprising the steps of:
forming a lower interconnection above a substrate;
forming a first protective film made of silicon carbide so as to cover one surface of said lower interconnection;
forming a second protective film made of an insulating material on said first protective film;
forming a third protective film made of silicon carbide on said second protective film;
forming an interlayer insulating film on said third protective film;
forming a hole in said interlayer insulating film by using said third protective film as a stopper;
processing an upper layer portion of said interlayer insulating film in a portion aligned with said hole;
processing said second and first protective films so as to be aligned with said hole, thereby exposing said one surface of said lower interconnection to said hole; and
burying a conductive material in at least said hole.

3. The method according to claim 2, wherein said second protective film is made thinner than said third protective film.

4. The method according to claim 1, wherein the first step comprises the steps of:
forming a groove having an interconnection shape in a lower insulating film formed above said substrate; and
filling said groove with a conductive material containing at least copper, thereby forming said lower interconnection.

5. The method according to claim 1, wherein said second protective film is made of a material having an etching rate lower than that of said interlayer insulating film.

6. The method according to claim 5, wherein in the third step, said second protective film is formed by a plasma CVD method.

7. The method according to claim 1, wherein the sixth step comprises the step of forming a groove having an interconnection shape in said interlayer insulating film so as to be aligned with said hole, and
the eighth step comprises the step of filling said hole and said groove with a conductive material containing at least copper, thereby forming an upper interconnection electrically connected to said lower interconnection.

8. The method according to claim 7, wherein, when said groove having an interconnection shape is to be formed in said interlayer insulating film so as to be aligned with said hole, said groove is formed after a filling material is buried in said hole, and said filling material is removed after forming said groove.

9. An interconnection structure formation method comprising the steps of:
forming a first protective film made of silicon carbide, a second protective film made of an insulating material, and an interlayer insulating film in this order so as to cover the surface of a lower interconnection;
forming a hole in said interlayer insulating film with using said second protective film as a stopper; and
removing a mask used in forming said hole while the surface of said second protective film is exposed to said hole.

10. An interconnection structure formation method comprising the steps of:
forming a first protective film made of silicon carbide, a second protective film made of an insulating material, a third protective film made of silicon carbide, and an interlayer insulating film in this order so as to cover one surface of a lower interconnection;
forming a hole in said interlayer insulating film by using said third protective film as a stopper; and
removing a mask used in forming said hole while a surface of said third or second protective film is exposed to said hole.

11. The method according to claim 10, wherein said second protective film is made thinner than said third protective film.

12. The method according to claim 9, further comprising the steps of, after removing said mask:
processing an upper portion of said interlayer insulating film in a portion aligned with said hole;
processing said second and first protective films so as to be aligned with said hole, thereby exposing the surface of said lower interconnection to said hole; and
burying a conductive material in at least said hole.

13. The method according to claim 10, further comprising the steps of, after removing said mask:
processing an upper layer portion of said interlayer insulating film in a portion aligned with said hole;
processing said third, second, and first protective films so as to be aligned with said hole, thereby exposing said one surface of said lower interconnection to said hole; and
burying a conductive material in at least said hole.

14. The method according to claim 9, wherein said mask is ashed with an oxygen plasma when removed.

15. The method according to claim 9, wherein said second protective film is made of a material having an etching rate lower than that of said interlayer insulating film.

16. The method according to claim 15, wherein said second protective film is formed by a plasma CVD method.

17. The method according to claim 9, further comprising the steps of, before forming said first protective film:
forming an insulating film above a substrate;
forming a first interconnection groove in said insulating film; and
filling said first interconnection groove with a conductive material containing at least copper, thereby forming said lower interconnection.

18. The method according to claim 17, further comprising the steps of, after removing said mask:
forming a second interconnection groove in said interlayer insulating film so as to be aligned with said hole; and
burying a conductive material containing at least copper in said second interconnection groove and said hole, thereby forming an upper interconnection electrically connected to said lower interconnection.

19. An interconnection structure comprising:
a lower interconnection formed above a substrate;
a first protective film made of silicon carbide and formed to cover said lower interconnection;
a second protective film made of an insulating material and formed on said first protective film;
an interlayer insulating film formed on said second protective film; and
an upper interconnection electrically connected to said lower interconnection through a hole formed in said interlayer insulating film, said second protective film and said first protective film.

20. An interconnection structure comprising:
a lower interconnection formed above a substrate;
a first protective film made of silicon carbide and formed to cover said lower interconnection;
a second protective film made of an insulating material and formed on said first protective film;
a third protective film made of silicon carbide and formed on said second protective film;
an interlayer insulating film formed on said third protective film; and
an upper interconnection electrically connected to said lower interconnection through a hole formed in said interlayer insulating film and said third, second, and first protective films.

21. The structure according to claim 20, wherein said lower interconnection is formed by burying a conductive material containing at least copper in a first interconnection groove formed in an insulating film formed above said substrate.

22. The structure according to claim 21, wherein said upper interconnection is formed by burying a conductive material containing at least copper in a second interconnection groove, which is formed in said interlayer insulating film so as to be aligned with the hole, and in said hole.

23. The structure according to claim 20, wherein said second protective film is a silicon nitride film.
